(19) United States
(12) Patent Application Publication
(10) Pub. No.: US 2026/0143850 A1
(43) Pub. Date: May 21, 2026

(54) ULTRA-SPEED PHOTODETECTOR

(71) Applicant: HLJ TECHNOLOGY CO., LTD., Hsinchu County (TW)

(72) Inventors: LI-HUNG LAI, Taoyuan City (TW); LI-WEN LAI, Taoyuan City (TW); BING-CHENG LIN, Hsinchu County (TW); YEN-CHUN TSENG, Hsinchu County (TW)

(21) Appl. No.: 19/016,000

(22) Filed: Jan. 10, 2025

(30) Foreign Application Priority Data
Nov. 21, 2024 (TW) 113144795

(51) Int. Cl. H10F 77/20; H10F 77/30

(52) U.S. Cl. CPC H10F 77/251; H10F 77/306

(57) ABSTRACT

An ultra-speed photodetector includes a substrate, a light-absorbing layer, and a light-transmitting electrode layer. The light-absorbing layer located on the substrate. The electrode disposed on the light-absorbing layer and divided into a plurality of first electrodes and a plurality of second electrodes. A polarity of the first electrode is opposite to a polarity of the second electrode. The plurality of first electrodes arranged at intervals, and the second electrode located between the two adjacent first electrodes. A gap located between the first electrode and the second electrode that were adjacent to each other, and a portion of a surface of the light-absorbing layer exposed at the gap.

### CROSS-REFERENCE TO RELATED PATENT APPLICATION

This application claims the benefit of priority to Taiwan Patent Application No. 113144795, filed on Nov. 21, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a photodetector, and more particularly to a photodetector includes a light-transmittance electrode layer.

### BACKGROUND OF THE DISCLOSURE

With the development of semiconductor technology, photons would be the medium to replace electrons in computing and data transmission in the next generation. Integrated circuits will become integrated photons circuits. With the current technology, photons will gradually replace electrons. The devices of high-efficiency electrons trans to photons and photons trans to electrons are important issues in related arts.

In the related art, due to the requirement for high-speed transmission, the depletion region of the PIN structure of the photodiode is thin. The number of photons that the photodiode can receive is limited, so the signal is weak. The thin depletion region of the PIN structure of the photodiode is detrimental to the development of the aforementioned technology.

Therefore, how to increase the photon absorption of the photodetector and improve the performance of the photodetector by designing the structural of the photodetector to overcome the above problems has become one of the important issues to be solved in the related arts.

### SUMMARY OF THE DISCLOSURE

In response to the above-referenced technical inadequacies, the present disclosure provides an ultra-speed photodetector.

In order to solve the above-mentioned problems, one of the technical aspects adopted by the present disclosure is to provide an ultra-speed photodetector includes a substrate, a light-absorbing layer, and a light-transmitting electrode layer. The light-absorbing layer located on the substrate. The electrode disposed on the light-absorbing layer and divided into a plurality of first electrodes and a plurality of second electrodes. A polarity of the first electrode is opposite to a polarity of the second electrode. The plurality of first electrodes arranged at intervals, and the second electrode located between the two adjacent first electrodes. A gap located between the first electrode and the second electrode that were adjacent to each other, and a portion of a surface of the light-absorbing layer exposed at the gap.

In one of the possible or preferred embodiments, a distance of the gap is 1-500 nm.

In one of the possible or preferred embodiments, a material of the light-transmitting electrode layer is indium tin oxide or zinc oxide.

In one of the possible or preferred embodiments, the light-transmitting electrode layer is an ultra-thin metal film.

In one of the possible or preferred embodiments, a thickness of the ultra-thin metal film is less than 3 nm or equal to 3 nm.

In one of the possible or preferred embodiments, the ultra-speed photodetector further includes an anti-reflection layer, the anti-reflection layer disposed on the light-transmitting electrode layer, and deposed on the surfaces of the light-absorbing layer exposed at the gaps.

In one of the possible or preferred embodiments, the ultra-speed photodetector further includes an energy barrier layer located between the light-absorbing layer and the light-transmitting electrode layer.

In one of the possible or preferred embodiments, the energy barrier layer is made of a wide bangap material, including at least one of amorphous silicon, silicon carbide, aluminum nitride, gallium nitride, diamond, zinc oxide or a combination thereof.

In one of the possible or preferred embodiments, the light-absorbing layer includes a plurality of trenches corresponding to the plurality of first electrodes and the plurality of second electrodes, and each of the first electrodes and each of the second electrodes respectively covers each of the trenches.

In one of the possible or preferred embodiments, the light-absorbing layer includes trivalent elements or pentavalent elements.

In one of the possible or preferred embodiments, a material of the substrate includes at least one of silicon, gallium arsenide, indium phosphide, germanium, silicon carbide, aluminum oxide, glass and graphite.

Therefore, in the ultra-speed photodetector provided by the present disclosure, by virtue of “a gap located between the first electrode and the second electrode that were adjacent to each other, and a portion of a surface of the light-absorbing layer exposed at the gap,” The surface of the light-absorbing layer of the ultra-speed photodetector can be receive a large number of photons, thereby improving the efficiency of photon transmission.

Further, with one embodiment of the present disclosure, by virtue of “a distance of the gap is 1-500 nm”, a very small gap between the first electrode and the second electrode, that can increase the electric field in the light-absorbing layer and accelerate the generation of photocurrent, thereby improving the performance of the ultra-speed photodetector.

Further, with one embodiment of the present disclosure, by virtue of “the ultra-speed photodetector further includes an energy barrier layer located between the light-absorbing layer and the light-transmitting electrode layer”, the ultra-speed photodetector can prevent photons from leaking out or being reflected, and greatly increasing the number of photons received.

Further, with one embodiment of the present disclosure, by virtue of “the ultra-speed photodetector further includes an energy barrier layer located between the light-absorbing layer and the light-transmitting electrode layer”, that can reduce the dark current generated when the ultra-speed photodetector is turned off or there is no light, and reducing the noise when the ultra-speed photodetector is operating.

Furthermore, according to one embodiment of the present disclosure, the energy barrier layer is an amorphous silicon layer full of defects. These defects can be used as traps to quickly capture electron carriers when the ultra-speed photodetector is turned off, and can be quickly turned off, thus enhancing the operating speed of ultra-speed photodetector.

Furthermore, according to one embodiment of the present disclosure, the light-absorbing layer includes the trenches, that can strengthen the electric field of the ultra-speed photodetector and improve the performance of the ultra-speed photodetector.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic cross-sectional view of an ultra-speed photodetector according to an embodiment of the present disclosure;

FIG. 2 is the schematic top view of an ultra-speed photodetector according to an embodiment of the present disclosure; and

FIG. 3 is another schematic cross-sectional view of an ultra-speed photodetector according to an embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

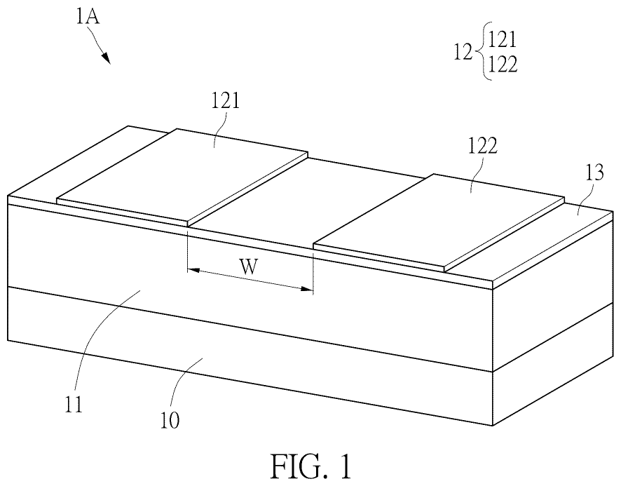

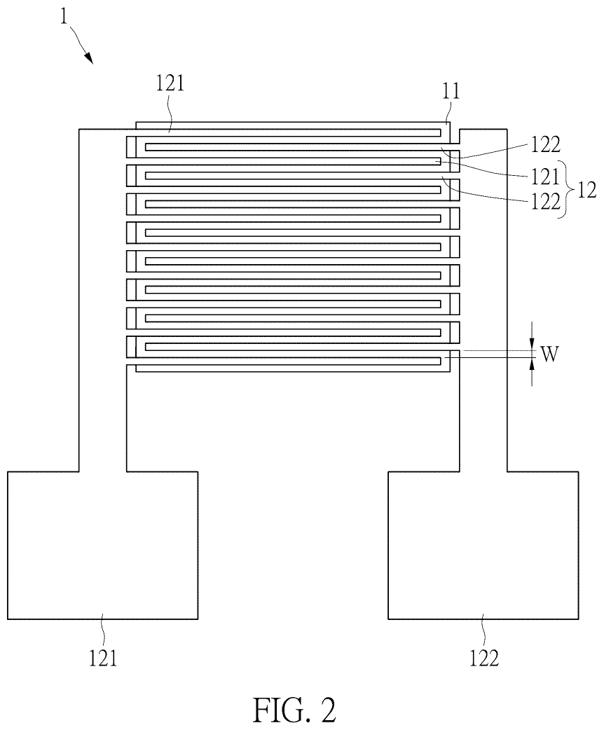

Referring to FIG. 1 to FIG. 2, an embodiment of the present disclosure provides an ultra-speed photodetector 1A. The ultra-speed photodetector 1A includes a substrate 10, a light-absorbing layer 11 and an electrode layer 12. The light-absorbing layer 11 is located on the substrate 10. The electrode layer 12 is light-transmissive. The electrode disposed on the light-absorbing layer 11 and divided into a plurality of first electrodes 121 and a plurality of second electrodes 122. A polarity of the first electrode is opposite to a polarity of the second electrode. The plurality of first electrodes 121 arranged at intervals, and the second electrode located between the two adjacent first electrodes 121. A gap W located between the first electrode and the second electrode that were adjacent to each other, and a portion of a surface of the light-absorbing layer 11 exposed at the gap W. According to some embodiments, a material of the light-absorbing layer 11 can absorb a full range of light waves. According to some embodiments, the light-absorbing layer 11 includes trivalent elements or pentavalent elements, such as aluminum gallium nitride (AlGaN). The light-absorbing layer 11 includes aluminum gallium nitride can absorb violet light or green light. According to some embodiments, the light-absorbing layer 11 includes aluminum gallium arsenide (AlGaAs). The light-absorbing layer 11 includes aluminum gallium arsenide can absorb red light or infrared light. According to other embodiments, the light-absorbing layer 11 includes indium phosphide (InP). The light-absorbing layer 11 includes indium phosphide can absorb SWIR light. As shown in FIG. 2, The first electrodes 121 are connected in series, and the second electrodes 122 are connected in series. The first electrode has a different polarity than the second electrode.

According to some embodiments, a material of the substrate 10 includes at least one of silicon, gallium arsenide, indium phosphide, germanium, silicon carbide, aluminum oxide, glass and graphite.

According to some embodiments, a distance of the gap W is 1-500 nm. In some embodiments, the gap W is 2 nm or 3 nm. With a small gap W between the first electrode and the second electrode, the electric field can be strengthened to increase a speed of photocurrent generation.

Since the electrode layer 12 is light-transmissive, the number of absorbed photons can be increased. According to some embodiments, a material of the electrode layer 12 is indium tin oxide or zinc oxide. According to some embodiments, the electrode layer 12 is an ultra-thin metal film. The thickness of ultra-thin metal film is less than or equal to 3 nm. With the thickness, the ultra-thin metal film is light-transmissive and can be used as an ultra-speed photodetector 1A, increasing the number of photons received by the light-absorbing layer 11. According to some embodiments, the ultra-speed photodetector 1A further includes an anti-reflection layer (not shown). The anti-reflection layer disposed on the electrode layer 12, and deposed on the surfaces of the light-absorbing layer 11 exposed at the gaps W. With the reflective layer, the photons received by the ultra-speed photodetector 1A can be “blocked” in the electrode layer 12 and the light-absorbing layer 11, making these photons less likely to leak or be reflected, so that to increase the number of photons received by the light-absorbing layer 11.

According to some embodiments, the ultra-speed photodetector 1A further includes an energy barrier layer 13 located between the light-absorbing layer 11 and the light-transmitting electrode layer 12. The energy barrier layer 13 can increase the energy level between the electrode layer 12 and the light-absorbing layer 11, reducing or preventing the generation of dark current (such as the microcurrent effect that occurs when the photodetector is not exposed to the light). According to some embodiments, the energy barrier layer 13 is made of a wide bangap material, including at least one of amorphous silicon, silicon carbide, aluminum nitride, gallium nitride, diamond, zinc oxide or a combination thereof.

In some situations, the energy barrier layer 13 is an amorphous silicon layer full of defects. These defects can serve as traps to quickly capture electron carriers when the ultra-speed photodetector 1A is turned off, thus shortening the turn-off time of the ultra-speed photodetector 1A, speeding up the operation of ultra-speed photodetector 1A.

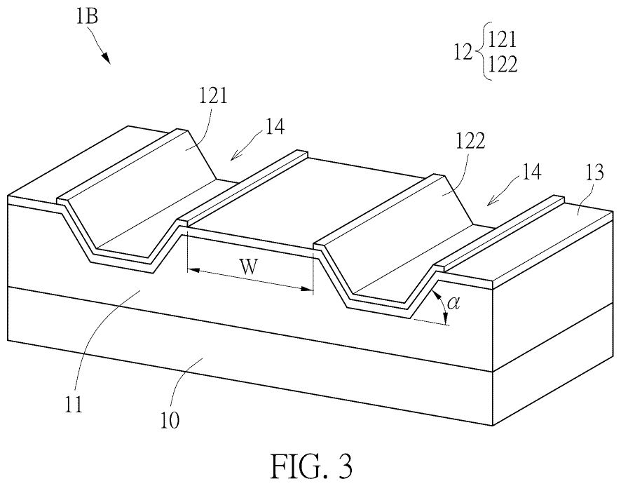

Referring to FIG. 3, another embodiment of the present disclosure provides an ultra-speed photodetector 1B. The light-absorbing layer 11 includes a plurality of trenches 14 corresponding to the plurality of first electrodes 121 and the plurality of second electrodes 122, and each of the first electrodes 121 and each of the second electrodes 122 respectively covers each of the trenches 14. The trenches 14 can be square, V-shaped or U-shaped. With the trenches 14, the light-absorbing layer 11 can strength an electric field of the ultra-speed photodetector 1B and improve the performance of the ultra-speed photodetector 1B.

### Beneficial Effects of the Embodiments

In conclusion, in the ultra-speed photodetector provided by the present disclosure, by virtue of “a gap located between the first electrode and the second electrode that were adjacent to each other, and a portion of a surface of the light-absorbing layer exposed at the gap,” The surface of the light-absorbing layer of the ultra-speed photodetector can be receive a large number of photons, thereby improving the efficiency of photon transmission.

Further, with one embodiment of the present disclosure, by virtue of “a distance of the gap is 1-500 nm”, a very small gap between the first electrode and the second electrode, that can increase the electric field in the light-absorbing layer and accelerate the generation of photocurrent, thereby improving the performance of the ultra-speed photodetector.

Further, with one embodiment of the present disclosure, by virtue of “the ultra-speed photodetector further includes an energy barrier layer located between the light-absorbing layer and the light-transmitting electrode layer”, the ultra-speed photodetector can prevent photons from leaking out or being reflected, and greatly increasing the number of photons received.

Further, with one embodiment of the present disclosure, by virtue of “the ultra-speed photodetector further includes an energy barrier layer located between the light-absorbing layer and the light-transmitting electrode layer”, that can reduce the dark current generated when the ultra-speed photodetector is turned off or there is no light, and reducing the noise when the ultra-speed photodetector is operating.

Furthermore, according to one embodiment of the present disclosure, the energy barrier layer is an amorphous silicon layer full of defects. These defects can be used as traps to quickly capture electron carriers when the ultra-speed photodetector is turned off, and can be quickly turned off, thus enhancing the operating speed of ultra-speed photodetector.

Furthermore, according to one embodiment of the present disclosure, the light-absorbing layer includes the trenches, that can strengthen the electric field of the ultra-speed photodetector and improve the performance of the ultra-speed photodetector.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An ultra-speed photodetector, comprising:
a substrate;
a light-absorbing layer located on the substrate; and
a light-transmitting electrode layer, the electrode disposed on the light-absorbing layer and divided into a plurality of first electrodes and a plurality of second electrodes;
wherein a polarity of the first electrode is opposite to a polarity of the second electrode;
wherein the plurality of first electrodes arranged at intervals, and the second electrode located between the two adjacent first electrodes; and
wherein a gap located between the first electrode and the second electrode that were adjacent to each other, and a portion of a surface of the light-absorbing layer exposed at the gap.

2. The ultra-speed photodetector according to claim 1, wherein a distance of the gap is 1-500 nm.

3. The ultra-speed photodetector according to claim 1, where a material of the light-transmitting electrode layer is indium tin oxide or zinc oxide.

4. The ultra-speed photodetector according to claim 1, where the light-transmitting electrode layer is an ultra-thin metal film.

5. The ultra-speed photodetector according to claim 4, where a thickness of the ultra-thin metal film is less than 3 nm or equal to 3 nm.

6. The ultra-speed photodetector according to claim 1, further comprising an anti-reflection layer, the anti-reflection layer disposed on the light-transmitting electrode layer, and deposed on the surfaces of the light-absorbing layer exposed at the gaps.

7. The ultra-speed photodetector according to claim 1, further comprising an energy barrier layer located between the light-absorbing layer and the light-transmitting electrode layer.

8. The ultra-speed photodetector according to claim 7, wherein the energy barrier layer is made of a wide bangap material, including at least one of amorphous silicon, silicon carbide, aluminum nitride, gallium nitride, diamond, zinc oxide or a combination thereof.

9. The ultra-speed photodetector according to claim 1, wherein, the light-absorbing layer includes a plurality of trenches corresponding to the plurality of first electrodes and the plurality of second electrodes, and each the first electrodes and each the second electrodes respectively covers each the trenches.

10. The ultra-speed photodetector according to claim 1, wherein the light-absorbing layer includes trivalent elements or pentavalent elements.

11. The ultra-speed photodetector according to claim 1, wherein a material of the substrate includes at least one of silicon, gallium arsenide, indium phosphide, germanium, silicon carbide, aluminum oxide, glass and graphite.
